(19) United States
(12) Patent Application Publication
(10) Pub. No.: US 2019/0386282 A1
(43) Pub. Date: Dec. 19, 2019

(54) CONNECTION MODULE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Osamu NAKAYAMA, Mie (JP); Kotaro TAKADA, Mie (JP); Mitsutoshi MORITA, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 16/487,631

(22) PCT Filed: Feb. 19, 2018
(86) PCT No.: PCT/JP2018/005684

§ 371 Date: Aug. 21, 2019

(30) Foreign Application Priority Data
Mar. 3, 2017 (JP) 2017-040360

(51) Int. Cl. H01M 2/20; H05K 1/18; H01G 2/06; H01R 25/16; H01R 12/71; H01M 10/48

(52) U.S. Cl. CPC H01M 2/206; H05K 1/181; H01G 2/06; H01R 25/162; H01M 2220/20; H01M 10/482; H05K 2201/10015; H05K 2201/10272; H05K 2201/10037; H01R 12/71

(57) ABSTRACT

A connection module includes metal bus bars for electrically connecting adjacent ones of a plurality of power storage modules, a circuit board on which electronic components are mounted, and an insulating protector that is made of an insulating synthetic resin and includes a bottom wall, a board arrangement portion that protrudes from the bottom wall and in which the circuit board is to be arranged, and bus bar arrangement portions that protrude from the bottom wall and in which the bus bars are to be arranged.

### TECHNICAL FIELD

The technology disclosed in the present specification relates to a connection module for connecting a plurality of power storage modules to each other.

### BACKGROUND ART

A power storage module for use in an electric automobile or a hybrid vehicle includes a power storage element group composed of a plurality of power storage elements arranged side-by-side and a wiring module attached thereto, which is provided with bus bars for connecting electrodes of the respective power storage elements and detection wires for detecting voltage. The plurality of power storage elements are electrically connected to each other by the bus bars provided in the wiring module.

Furthermore, a plurality of power storage modules are electrically connected to each other by connecting external connection terminals provided in the respective power storage modules using bus bars. Also, for such connection of power storage modules, there are cases where a connection module for collectively holding the bus bars and a plurality of detection wires drawn out from the respective power storage modules is used.

### CITATION LIST

### Patent Document

Patent Document 1: JP 2014-22157A

### SUMMARY OF INVENTION

### Technical Problem

In recent times, demand for higher output of power storage modules has led to a trend where the number of power storage elements incorporated in one power storage module is increased and also the number of power storage modules is increased. However, this poses a concern that, in a case where the state of a plurality of power storage elements is to be monitored by one control unit, the number of detection wires increases, which results in an increase in the number of connection circuits between the detection wires and the control unit.

To address this issue, it has been proposed to provide, for every predetermined number of power storage elements, a sensing unit for monitoring the state of the power storage elements in a connection module, and connecting respective sensing units and the control unit using signal lines. With this configuration, the number of signal lines drawn out from the sensing units can be made smaller than the number of detection wires connected to the power storage elements. Accordingly, there were expectations of being able to reduce the number of connection circuits between the signal lines and the control unit.

However, according to the above configuration, although the number of connection circuits between the sensing unit and the control unit can be reduced, the connection module needs a space in which the sensing units are to be arranged. For this reason, there is a concern that the size of the connection module may increase as a whole.

The technology disclosed in the present specification was achieved in light of the foregoing situation, and an object thereof is to realize miniaturization of a connection module as a whole.

### Solution to Problem

The technology disclosed in the present specification relates to a connection module for electrically connecting a plurality of power storage modules each provided with a plurality of storage elements, including: a metal bus bar for electrically connecting adjacent ones of the plurality of power storage modules; a circuit board on which an electronic component is mounted; and an insulating protector that is made of insulating synthetic resin and includes a bottom wall, a board arrangement portion that protrudes from the bottom wall and in which the circuit board is to be arranged, and a bus bar arrangement portion that protrudes from the bottom wall and in which the bus bar is to be arranged.

According to the above configuration, the circuit board and the bus bar can be arranged integrally in the insulating protector, and this enables the miniaturization of the connection module as a whole.

The following aspects are preferable as aspects for carrying out the technology disclosed in the present specification.

It is preferable that a protruding dimension of the board arrangement portion as measured from the bottom wall is set to be smaller than a protruding dimension of the bus bar arrangement portion as measured from the bottom wall.

Since the circuit board has the electronic component mounted thereon, the height dimension of the circuit board is larger than that of the bus bar, which has a plate shape. Accordingly, in order to miniaturize the connection module, it is important to set a maximum height dimension of the circuit board in the state of being arranged in the insulating protector to be as small as possible. According to the above configuration, in the state where the circuit board is arranged in the insulating protector, the height position of the circuit board with respect to the bottom wall of the insulating protector can be made lower than the height position of the bus bar with respect to the bottom wall of the insulating protector. This enables miniaturization of the connection module as a whole.

It is preferable that a plurality of detection conductive paths for detecting a state of the plurality of power storage elements are drawn out from the plurality of power storage modules, the plurality of detection conductive paths and at least one output conductive path are electrically connected to the circuit board, and the electronic component on the circuit board multiplexes a plurality of signals input from the plurality of detection conductive paths and outputs the multiplexed signals to the output conductive path.

According to the above configuration, the number of output conductive paths can be made smaller than the number of the detection conductive paths. As a result, the number of components constituting the connection module can be reduced.

It is preferable that one end portions of a plurality of relay conductive paths are electrically connected to the circuit board, and a connection module-side connector is connected to the other end portions of the plurality of relay conductive paths, and the plurality of detection conductive paths and the plurality of relay conductive paths are electrically connected to each other by fitting together the connection module-side connector and a power storage module-side connector that is connected to end portions of the plurality of detection conductive paths.

According to the above configuration, electrical connection between the detection conductive paths and the relay conductive paths can be established easily through connection using a connector(s). With this configuration, the steps of assembling the connection module to the power storage modules can be simplified.

It is preferable that the insulating protector has a connector holding portion for holding the connection module-side connector.

According to the above configuration, it is possible to keep the connection module-side connector connected to the relay conductive paths from colliding with a foreign body owing to vibrations.

It is preferable that the insulating protector has a conductive path wiring portion in which one or both of the detection conductive paths and the relay conductive paths are to be arranged.

According to the above configuration, it is possible to keep the detection conductive paths or the relay conductive paths from getting caught on a foreign body.

It is preferable that an output wire is electrically connected to the circuit board, and the output wire is arranged in the conductive path wiring portion.

According to the above configuration, it is possible to keep the output wire from getting caught on a foreign body.

### Advantageous Effects of Invention

The technology disclosed in the present specification can realize miniaturization of a connection module as a whole.

### BRIEF DESCRIPTION OF DRAWINGS

FIG. 1 is a perspective view showing a power storage pack disclosed in a first embodiment.

FIG. 2 is a plan view showing a connection module.

FIG. 3 is an exploded perspective view showing the connection module.

FIG. 4 is a plan view showing the power storage pack.

FIG. 5 is a cross-sectional view taken along line A-A in FIG. 4.

FIG. 6 is a cross-sectional view taken along line B-B in FIG. 4.

FIG. 7 is a side view showing the power storage pack.

### DESCRIPTION OF EMBODIMENTS

### First Embodiment

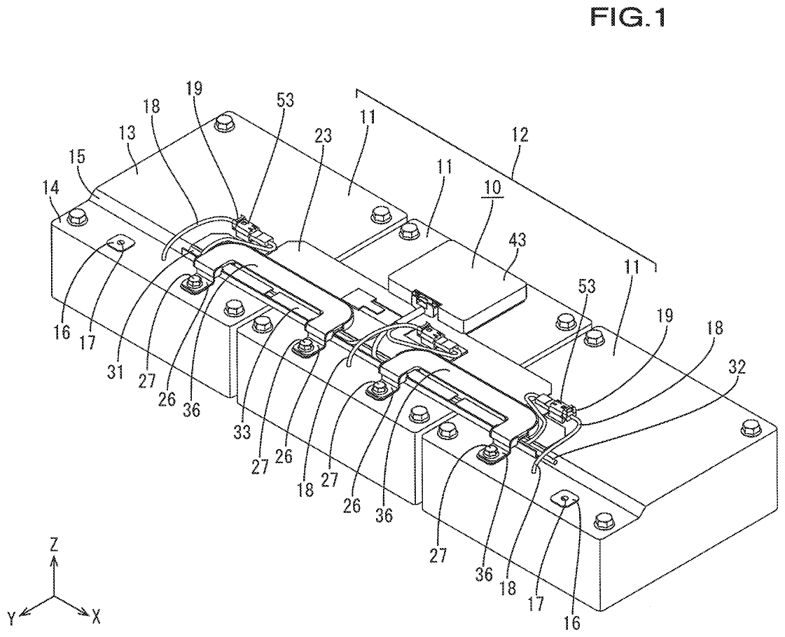

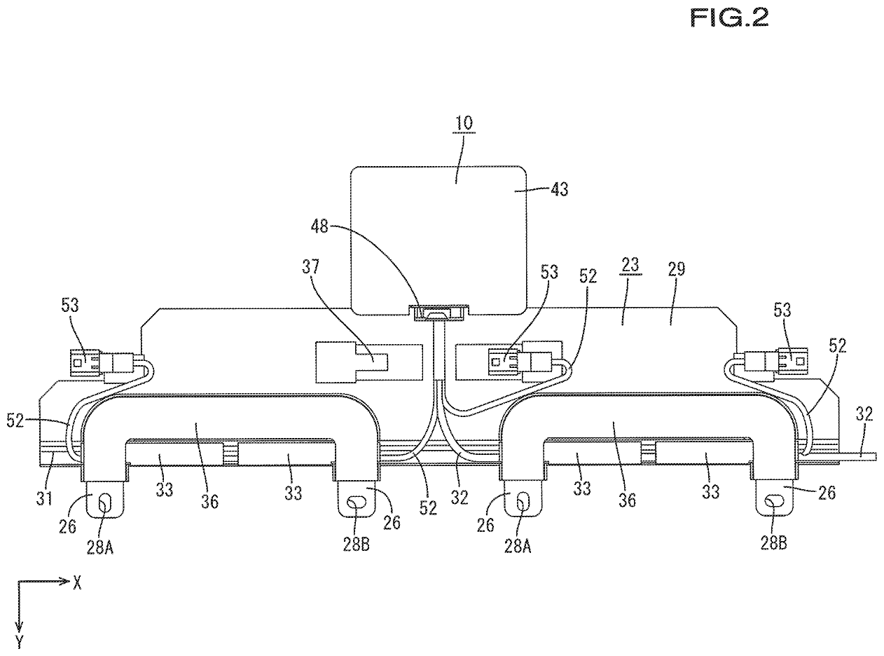

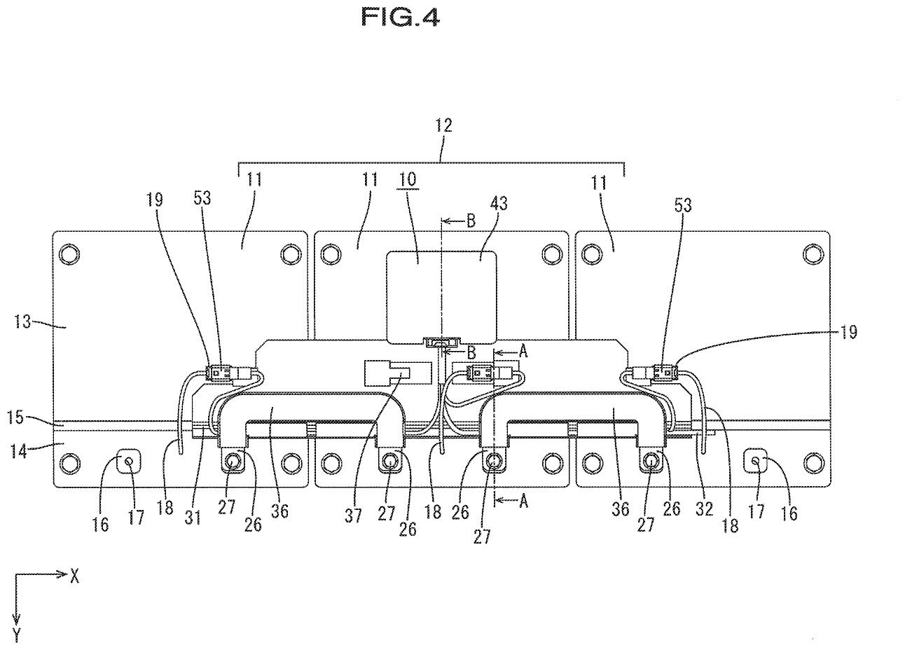

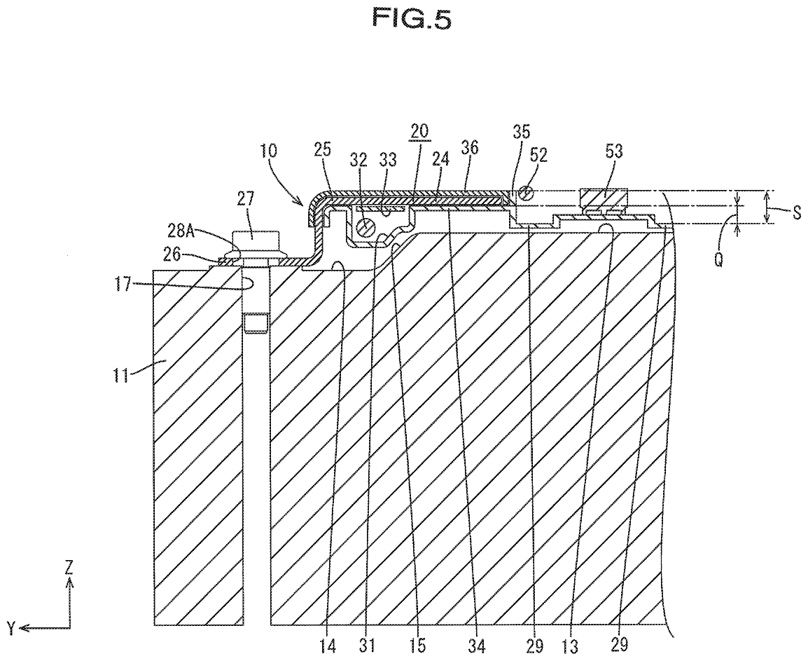

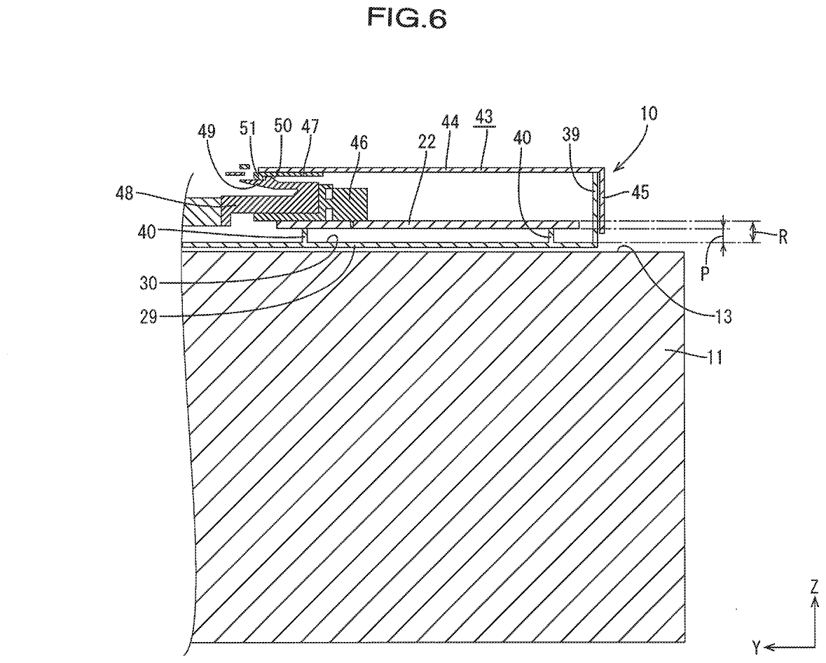

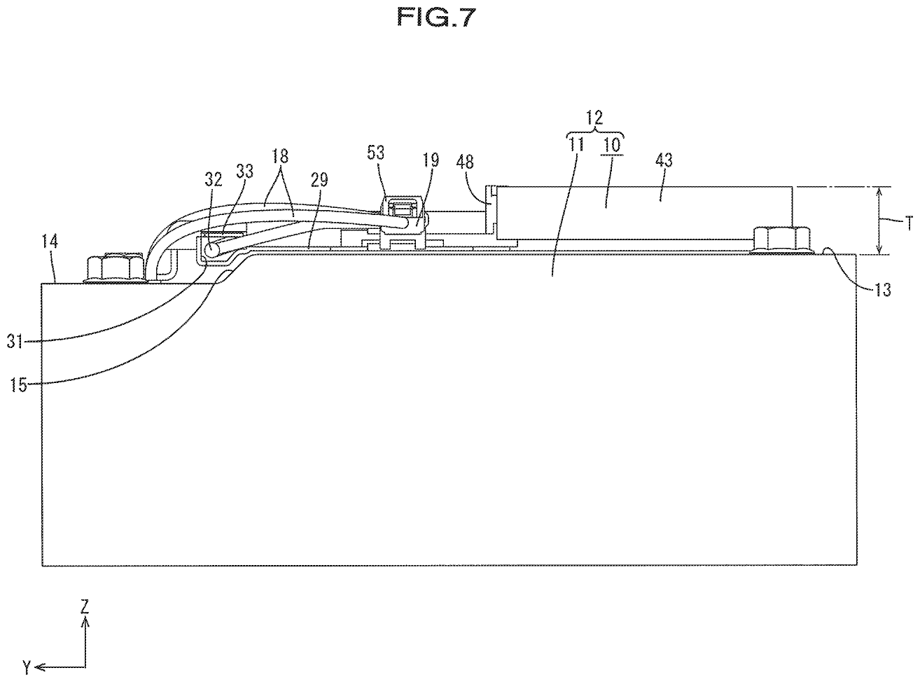

A first embodiment in which the technology disclosed in the present specification is applied to a connection module 10 will be described with reference to FIGS. 1 to 7. The connection module 10 according to the present embodiment is for electrically connecting a plurality of power storage modules 11 (three in the present embodiment) to each other. Each power storage module 11 includes a plurality of power storage elements (not shown). A power storage pack 12 is constituted by electrically connecting the plurality of power storage modules 11 to each other using the connection module 10. This power storage pack 12 is used as a driving source of an electric automobile, a hybrid automobile, or the like. In the following description, the X direction is considered to be the rightward direction, the Y direction is considered to be the forward direction, and the Z direction is considered to be the upward direction. For a plurality of identical members, a reference numeral may be assigned to one member only, and reference numerals may be omitted for the other members.

### Power Storage Module 11

The power storage modules 11 have a cuboid shape as a whole, and house the plurality of power storage elements (not shown) therein. The plurality of power storage elements may be configured such that all of the power storage elements are connected in series, all of the power storage elements are connected in parallel, or both power storage elements connected in series and power storage elements connected in parallel are present.

The upper surfaces of the power storage modules 11 each have an upper level portion 13 that occupies approximately two thirds of the area of the upper surface and extends from the rear edge toward the front on the upper surface, a lower level portion 14 that is located at a lower position than the upper level portion 13 and occupies the remaining one third of the area of the upper surface, and a step portion 15 that connects the upper level portion 13 and the lower level portion 14 in the vertical direction. The lower level portion 14 has two electrode terminals 16 provided so as to be spaced apart from each other in the left-right direction. One of the electrode terminals 16 is a positive electrode terminal, and the other is a negative electrode terminal. The plurality of power storage modules 11 are arranged side-by-side in a line along the left-right direction such that electrode terminals 16 with different polarities are adjacent to each other.

The electrode terminals 16 are made of metal and are rectangular when viewed from above. The metal constituting the electrode terminals 16 may be any metal selected as necessary, such as copper, a copper alloy, aluminum, or an aluminum alloy. The upper surface of each electrode terminal 16 is provided with a screw hole 17 that extends in the vertical direction.

A plurality of detection wires 18 (an example of detection conductive paths) for detecting the state of the power storage elements are drawn out from each power storage module 11. In FIG. 1, the plurality of detection wires 18 are depicted as a single bundle. The number of detection wires 18 drawn out from one power storage module 11 may be the same as, smaller than, or greater than the number of power storage elements provided in one storage module 11, and can be set to any number as necessary.

Power storage module-side connectors 19 are connected to the end portions of the detection wires 18 on the side opposite to the end drawn out from the power storage module 11. The power storage module-side connectors 19 are made of an insulating synthetic resin, and a plurality of cavities (not shown) for housing a plurality of terminals (not shown), respectively, are provided inside the power storage module-side connectors 19.

### Connection Module 10

For every predetermined number (three in the present embodiment) of storage modules 11, the connection module 10 is attached to the upper surfaces of the power storage modules 11. The connection module 10 includes metal bus bars 20 for electrically connecting the plurality of power storage modules 11, a circuit board 22 on which electronic components 21 are mounted, and an insulating protector 23 made of an insulating synthetic resin.

### Bus Bar 20

Each bus bar 20 is obtained by pressing a metal plate material into a predetermined shape. The metal material used to form the bus bars 20 may be any metal selected as necessary, such as copper, a copper alloy, stainless steel, aluminum, or an aluminum alloy. The surface of the bus bars 20 may be plated with any metal such as tin or nickel, as necessary.

Each bus bar 20 includes a main body portion 24 that has an elongated plate shape and a pair of extended portions 25 that extend from both end portions of the main body portion 24 in a direction intersecting the direction in which the main body portion 24 extends. The pair of extended portions 25 extend in the same direction with respect to the direction in which the main body 24 extends. The extended portions 25 are each bent in a crank shape when viewed from a side. Portions of the extended portions 25 toward the leading end portions thereof are connection portions 26, which are located lower than the main body portion 24. The connection portions 26 have insertion holes 28A and 28B for insertion of bolts 27.

Of the two insertion holes 28A and 28B formed in one bus bar 20, one, namely, the insertion hole 28A, is an elongated hole that extends in the front-rear direction, and the other insertion hole, namely, the insertion hole 28B, is an elongated hole that extends in the left-right direction. With this configuration, the bus bars 20 can move in the left-right direction and the front-rear direction according to the assembly tolerance when the plurality of power storage elements are arranged side-by-side and the manufacturing tolerance of the power storage elements.

### Insulating Protector 23

The insulating protector 23 is made of an insulating synthetic resin, and by and large has an elongated shape in the left-right direction. The insulating protector 23 has a bottom wall 29. The bottom wall 29 has, substantially at the center thereof in the left-right direction, a board housing portion 30 that protrudes rearward and houses the circuit board 22.

At the front end edge of the bottom wall 29, a wiring groove 31 (an example of a conductive path wiring portion) is provided so as to be elongated in the left-right direction and be recessed downward. In other words, the wiring groove 31 is formed in a shape that extends in the left-right direction and is open upward. The above-described plurality of detection wires 18 and a plurality of output wires 32 to be described below are arranged inside the wiring groove 31.

Wire covers 33 are attached to the wiring groove 31 from above in the state where the plurality of detection wires 18 and the plurality of output wires 32 are arranged in the wiring groove 31. Each wire cover 33 is made of an insulating synthetic resin and has an elongated plate shape in the left-right direction. The wire covers 33 keep the plurality of detection wires 18 and the plurality of output wires 32 from coming out of the wiring groove 31 and also keep the plurality of detection wires 18 and the plurality of output wires 32 from coming into contact with a foreign body.

At positions toward the front end portion of the bottom wall 29, two bus bar arrangement portions 34 are provided so as to be spaced apart from each other in the left-right direction. The bus bars 20 are to be arranged in the bus bar arrangement portions 34. Each bus bar arrangement portion 34 is formed in a trapezoidal shape so as to protrude upward from the bottom wall 29. When viewed from above, the bus bar arrangement portions 34 have substantially the same shape as the bus bars 20 and are also formed so as to be the same size as or slightly larger than the outer shape of the bus bar 20. With this configuration, the bus bars 20 can be placed on the bus bar arrangement portions 34.

A side wall 35 that stands upward is provided along the outer peripheral edge of each bus bar arrangement portion 34. A bus bar 20 is placed into the space surrounded by this side wall 35 from above to be housed therein. The height dimension of the side walls 35 protruding from the bottom wall 29 is set to be larger than the thickness dimension of the bus bars 20.

Bus bar covers 36 made of an insulating synthetic resin are to be attached to the bus bar arrangement portions 34 from above. As a result, the bus bars 20 housed in the bus bar arrangement portions 34 are covered by the bus bar covers 36. The bus bar covers 36 are formed in a shape corresponding to the shape of the bus bar arrangement portions 34. Although not shown in detail, the bus bar covers 36 and the bus bar arrangement portions 34 are attached integrally using a known locking structure.

Portions of the bus bar arrangement portions 34 toward the front end portions thereof are divided in the front-rear direction by the wiring groove 31 extending in the left-right direction. In the bus bar arrangement portions 34, portions located forward of the wiring groove 31 are bent downward.

In the insulating protector 23, connector holding portions 37 that protrude upward from the bottom wall 29 and extend either to the left or to the right are provided rearward of the bus bar arrangement portions 34. Each connector holding portion 37 has a rectangular plate shape when viewed from above. A connection module-side connector 53 to be described below is attached to each connector holding portion 37.

As described above, in the insulating protector 23, the board housing portion 30 that protrudes rearward is provided rearward of the region where the connector holding portions 37 are provided. The board housing portion 30 is rectangular when viewed from above, and has a shape slightly larger than the circuit board 22. Along both the left and right side edges and the rear edge of the board housing portion 30, a side wall 39 that protrudes upward is formed so as to stand upward from the bottom wall 29. In the board housing portion 30, the circuit board 22 is housed in a region surrounded by the side wall 39 on three sides.

In the board housing portion 30, a rib-like board arrangement portion 40 that protrudes upward from the bottom wall 29 is provided inside the region surrounded by the side wall 39 on the three sides. The board arrangement portion 40 has a substantially rectangular shape that is slightly smaller than the circuit board 22 when viewed from above. Screw holes 41 formed so as to extend in the vertical direction are provided at the four corners of the board arrangement portion 40. The circuit board 22 is fixed to the board arrangement portion 40 by screwing screws 42 into the screw holes 41 with the circuit board 22 interposed therebetween.

The upper opening of the board housing portion 30 is covered by a board cover 43 made of a synthetic resin. The board cover 43 includes a rectangular upper plate 44 and a side wall 45 that extends downward from side edges of the upper plate. The upper plate 44 of the board cover 43 is formed in a shape that is the same as or slightly larger than the shape of the board housing portion 30. The side wall 45 of the board cover 43 is provided so as to be located on the outside of the side wall 39 of the board housing portion 30 in a state where the board cover 43 is attached to the board housing portion 30. Although not shown in detail, the board cover 43 and the board housing portion 30 are attached integrally using a known locking structure.

The circuit board 22 includes an insulated board on which a conductive pattern (not shown) is formed using known printed wiring technology. The electronic components 21 are electrically connected to this conductive pattern using a known method such as soldering. In other words, the electronic components 21 are mounted on the circuit board 22. The conductive pattern may be formed on the upper surface, the lower surface, or both the upper surface and the lower surface of the circuit board 22. The circuit board 22 may be a so-called build-up board and may have laminated conductive patterns therein.

The circuit board 22 has a rectangular shape with rounded corners. At positions toward the four corners of the circuit board 22, insertion holes 54 for insertion of the screws 42 are formed extending through the circuit board 22.

A board connector 46 is attached, substantially at the center in the left-right direction, to the front end portion of the circuit board 22. The board connector 46 has a hood portion 47 that is open forward. The board connector 46 is provided with a tab terminal (not shown). One end portion of the tab terminal is in the hood portion 47. The other end portion of the tab terminal passes through the board connector 46 to protrude rearward, further bends downward, and is electrically connected to the conductive pattern of the circuit board 22 using a known method such as soldering.

A relay connector 48 is fitted into the hood portion 47 of the board connector 46. The upper surface of the relay connector 48 has a locking arm 49 that extends rearward from the front end portion of the relay connector 48. The locking arm 49 is formed so as to be elastically deformable in the vertical direction. A locking protrusion 50 that protrudes upward is provided at a position toward the rear end portion of the locking arm 49. This locking protrusion 50 serves to keep the relay connector 48 from being detached rearward from the hood portion 47 of the board connector 46 by locking with a locked portion 51 provided in the hood portion 47 of the board connector 46.

A plurality of relay wires 52 (an example of relay conductive paths) and an output wire 32 (an example of an output conductive path) are drawn out from the rear surface of the relay connector 48.

An end portion of the output wire 32 drawn out from the relay connector 48 is electrically connected to a control unit (not shown). The control unit monitors the state of the plurality of power storage elements on the basis of signals obtained from the output wire 32.

A terminal (not shown) is connected to one end portions of the relay wires 52. This terminal is housed in a cavity (not shown) formed inside the relay connector 48.

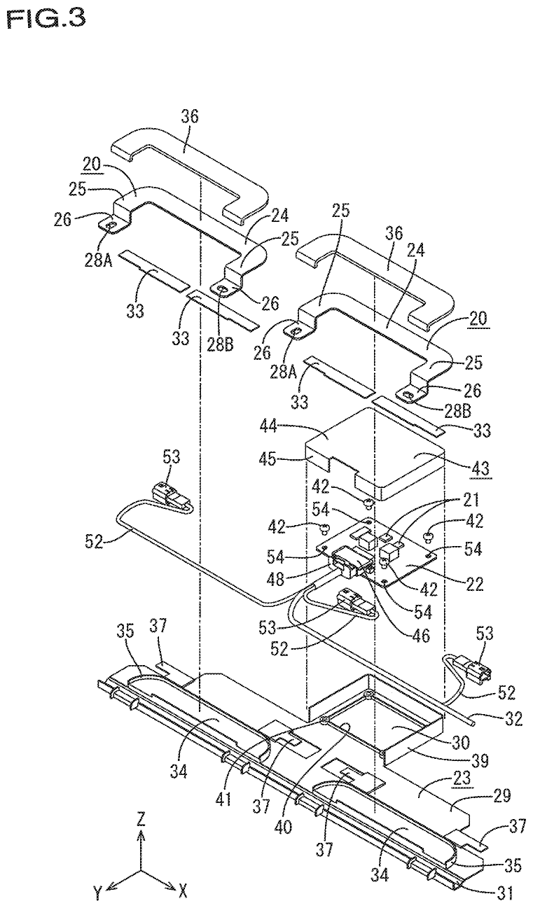

FIG. 3 shows the relay wires 52 drawn out from the relay connector 48. The plurality of relay wires 52 are divided into groups made up of a predetermined number of relay wires 52 and bundled to constitute wire bundles. In the drawings, each bundle of relay wires 52 is shown with its outline, and the shapes of the plurality of relay wires 52 constituting the wire bundle are not depicted.

Out of the end portions of the relay wires 52, a connection module-side connector 53 is connected to the end portions on the side opposite to the end portion introduced into the relay connector 48. The connection module-side connectors 53 are provided with a plurality of cavities (not shown) for housing a plurality of terminals (not shown) connected to the end portions of the relay wires 52. The outer surface of each connection module-side connector 53 has a receiving portion (not shown) that has a shape corresponding to the shape of the connector holding portions 37. The connection module-side connectors 53 can be attached to the connector holding portions 37 by housing the connector holding portion 37 inside this receiving portion.

### Electrical Connection Structure

As a result of fitting the power storage module-side connectors 19 connected to the end portions of the plurality of detection wires 18 drawn out from one storage module 11 to the connection module-side connectors 53, the detection wires 18 and the relay wires 52 are electrically connected to each other. Also, as a result of fitting the relay connector 48 to the board connector 46, the relay wires 52 and the circuit board 22 are electrically connected to each other. As a result, the detection wires 18 and the electronic components 21 provided on the circuit board 22 are electrically connected to each other. Also, the electronic components 21 provided on the circuit board 22 and the output wire 32 are electrically connected to each other. Although not shown in detail, the output wire 32 is electrically connected to the control unit, and thus, the detection wires 18 and the control unit are electrically connected to each other.

### Relationship Between Height Position of Bus Bars 20 and Height Position of Circuit Board 22

The protruding dimension P of the bus bar arrangement portion 40 as measured from the bottom wall 29 of the insulating protector 23 is set to be smaller than the protruding dimension Q of each bus bar arrangement portion 34 as measured from the bottom wall 29 of the insulating protector 23. The height dimension R of the upper surface of the circuit board 22 in the state of being arranged in the board arranging portion 40 as measured from the bottom wall 29 of the insulating protector 23 is set to be smaller than the height dimension S of the upper surface of each bus bar cover 36 in the state of being arranged in the bus bar arrangement portion 34 as measured from the bottom wall 29 of the insulating protector 23.

### Output Wire 32

The number of output wires 32 electrically connected to one circuit board 22 is set to be smaller than the number of the detection wires 18 electrically connected to the one circuit board 22. The electronic components 21 provided on the circuit board 22 multiplex signals relating to the state of the plurality of power storage elements input from the plurality of detection wires 18 via the plurality of relay wires 52 and output the multiplexed signals to the output wire 32.

### Steps of Assembling Connection Module 10

Subsequently, an example of the steps of assembling the connection module 10 will be described. It is to be noted that the steps of assembling the connection module 10 are not limited to those described below.

The bus bars 20 are formed by pressing a metal plate material into a predetermined shape. The insulating protector 23, the board cover 43, and the wire covers 33 are formed by injection molding an insulating synthetic resin.

A terminal is connected to one end portions of the relay wires 52, and this terminal is housed in the cavity of the relay connector 48. A terminal is connected to the other end portions of the relay wires 52, and this terminal is housed in a cavity of the connection module-side connector 53.

A terminal is connected to one end portion of the output wire 32, and this terminal is housed in the cavity of the relay connector 48.

The electronic components 21 and the board connector 46 are connected to the conductive path of the circuit board 22 using a known method such as reflow soldering. The circuit board 22 is arranged in the board arrangement portion 40 of the insulating protector 23, and the screws 42 are inserted into the insertion holes 54 and screwed into the screw holes 41. As a result, the circuit board 22 is fixed to the board arrangement portion 40. Next, the board cover 43 is attached to the insulating protector 23.

The relay wires 52 and the output wire 32 are arranged in the wiring groove 31 of the insulating protector 23, and the wire covers 33 are attached to the insulating protector 23. Subsequently, the connection module-side connectors 53 are attached to the connector holding portions 37 of the insulating protector 23. The bus bars 20 are arranged in the bus bar arrangement portions 34 of the insulating protector 23, and the bus bar covers 36 are attached to the insulating protector 23. The terminal connected to one end portions of the relay wires 52 is housed in the cavity of the relay connector 48. The relay connector 48 is fitted to the board connector. Thus, the connection module 10 is completed.

Subsequently, a plurality of power storage elements are arranged side-by-side and connected to each other using wiring modules to form a plurality of power storage modules 11. The plurality of power storage modules 11 are aligned in the left-right direction. The detection wires 18 are drawn out from each power storage module 11, and a terminal is connected to the end portions of the detection wires 18. This terminal is housed in the cavity of the power storage module-side connector 19.

The connection module 10 is attached to the upper surfaces of the power storage modules 11. The bolts 27 are inserted into the insertion holes 28A and 28B of the bus bars 20 and screwed into the screw holes 17 of the electrode terminals 16, whereby the bus bars 20 and the electrode terminals 16 are electrically connected to each other. Each power storage module-side connector 19 connected to the end portions of the detection wires 18 is fitted to a connection module-side connector 53. The end portion of the output wire 32 is connected to the control unit. Thus, the power storage pack 12 is completed.

### Actions and Effects of Present Embodiment

The following describes actions and effects of the present embodiment. A connection module 10 according to the present embodiment is a connection module for electrically connecting a plurality of power storage modules 11 each provided with a plurality of storage elements. The connection module 10 includes metal bus bars 20 for electrically connecting adjacent ones of a plurality of power storage modules 11, a circuit board 22 on which electronic components 21 are mounted, and an insulating protector 23 that is made of insulating synthetic resin and includes a bottom wall 29, a board arrangement portion 40 that protrudes from the bottom wall 29 and in which the circuit board 22 is arranged, and bus bar arrangement portions 34 that protrude from the bottom wall 29 and in which the bus bars 20 are to be arranged.

According to the above configuration, the circuit board 22 and the bus bars 20 can be arranged integrally in the insulating protector 23, which enables the miniaturization of the connection module 10 as a whole.

The protruding dimension P of the board arrangement portion 40 as measured from the bottom wall 29 is set to be smaller than the protruding dimension Q of each bus bar arrangement portion 34 as measured from the bottom wall 29.

Since the circuit board 22 has the electronic components 21 mounted thereon, the height dimension of the circuit board 22 including the electronic components 21 is larger than that of the bus bars 20. On this account, in order to miniaturize the connection module 10, it is important to set a maximum height dimension of the circuit board 22 in the state of being arranged in the insulating protector 23 to be as small as possible. According to the above configuration, in the state where the circuit board 22 is arranged in the insulating protector 23, the height position of the circuit board 22 with respect to the bottom wall 29 of the insulating protector 23 can be made lower than the height position of the bus bars 20 with respect to the bottom wall 29 of the insulating protector 23. This enables the miniaturization of the connection module 10 as a whole. As a result, the height dimension T from the upper surface of the power storage module 11 to the upper surface of the connection module 10 can be reduced.

The plurality of detection wires 18 for detecting the state of the plurality of power storage elements are drawn out from the plurality of power storage modules 11, the plurality of detection wires 18 and at least one output wire 32 are electrically connected to the circuit board 22, and the electronic components 21 on the circuit board 22 multiplex signals input from the plurality of detection wires 18 and output the multiplexed signals to the output wire 32.

According to the above configuration, the number of output conductive paths can be made smaller than the number of detection wires 18. As a result, the number of components constituting the connection module 10 can be reduced.

One end portions of the plurality of relay wires 52 are electrically connected to the circuit board 22, and the connection module-side connector 53 is connected to the other end portions of the plurality of relay wires 52. The plurality of detection wires 18 and the plurality of relay wires 52 are electrically connected to each other by fitting the power storage module-side connector 53 to the power storage module-side connector 19 connected to the end portions of the plurality of detection wires 18.

According to the above configuration, electrical connection between the detection wires 18 and the relay wires 52 can be established easily through connection using a connector(s). With this configuration, the steps of assembling the connection module 10 to the power storage modules 11 can be simplified.

In the present embodiment, the circuit board 22 is housed in the board housing portion 30 provided in the insulating protector 23. Accordingly, as compared with a case where the insulating protector 23 and a case for housing the circuit board 22 are provided separately, the number of components can be reduced. Furthermore, the number of man-hours required for attaching the case for housing the circuit board 22 to the insulating protector 23 can be reduced.

The insulating protector 23 has the connector holding portions 37 for holding the connection module-side connectors 53.

According to the above configuration, it is possible to keep the connection module-side connectors 53 connected to the relay wires 523 from colliding with a foreign body owing to vibrations.

The insulating protector 23 has the wiring groove 31 in which one or both of the detection wires 18 and the relay wires 52 are to be arranged.

According to the above configuration, it is possible to keep the detection wires 18 or the relay wires 52 from getting caught on a foreign body.

The output wire 32 is electrically connected to the circuit board 22, and the output wire 32 is arranged in the wiring groove 31.

According to the above configuration, it is possible to keep the output wire 32 from getting caught on a foreign body.

### Other Embodiments

The technology disclosed in the present specification is not intended to be limited to the embodiment described using the above descriptions and the drawings, and the technical scope of the technology disclosed in the present specification also encompasses various embodiments such as the following, for example.

(1) Although the detection wires 18 are used as the detection conductive paths in the present embodiment, there is no limitation to this, and a flexible printed circuit (FPC), flexible flat cables (FFCs), or the bus bars 20 may be used as the detection conductive paths.

(2) Although the relay wires 52 are used as the relay conductive paths in the present embodiment, there is no limitation to this, and a flexible printed circuit (FPC), flexible flat cables (FFCs), or the bus bars 20 may be used as the detection conductive paths.

(3) Although the output wire 32 is used as the output conductive path in the present embodiment, there is no limitation to this, and a flexible printed circuit (FPC), a flexible flat cable (FFC), or the bus bars 20 may be used as the output conductive path.

(4) The board cover 43 may be made of metal. In this case, the circuit board 22 can be electromagnetically shielded.

(5) The relay conductive paths may be omitted. In this case, the detection conductive paths can be electrically connected to the circuit board 22 by arranging a connector at the end portions of the detection conductive paths and fitting this connector to the board connector.

(6) The power storage element may be a secondary battery such as a lithium-ion secondary battery or a nickel-hydrogen secondary battery, or may be a capacitor.

(7) In the present embodiment, the connection module 10 is attached for every three power storage modules 11. However, there is no limitation to this, and the connection module 10 may be attached for every two power storage modules 11, or alternatively, for every four or more power storage modules.

(8) The number of the power storage modules 11 connected using the connection module 10 may be two, or may be four or more.

(9) In the present embodiment, the detection wires 18 are configured to detect the voltages of the power storage elements. However, there is no limitation to this, and the detection wires 18 may be configured to detect the temperatures of the power storage elements or to detect the currents of the power storage elements.

(10) The directions described in the embodiment are used for convenience of description. The power storage pack 12, the connection module 10, and the power storage modules 11 may be arranged so as to extend in any direction.

### LIST OF REFERENCE NUMERALS

10 Connection module
11 Power storage module
18 Detection wire
19 Power storage module-side connector
20 Bus bar
21 Electronic component
22 Circuit board
23 Insulating protector
29 Bottom wall
31 Wiring groove (conductive path wiring portion)
32 Output wire
34 Bus bar arrangement portion
37 Connector holding portion
40 Board arrangement portion
53 Connection module-side connector
P Protruding dimension of board arrangement portion as measured from bottom wall portion
Q Protruding dimension of bus bar arrangement portion as measured from bottom wall portion

1. A connection module for electrically connecting a plurality of power storage modules each provided with a plurality of storage elements, the connection module comprising:
a metal bus bar for electrically connecting adjacent ones of the plurality of power storage modules;
a circuit board on which an electronic component is mounted; and
an insulating protector that is made of an insulating synthetic resin and includes a bottom wall, a board arrangement portion that protrudes from the bottom wall and is configured to hold the circuit board, and a bus bar arrangement portion that protrudes from the bottom wall and is configured to hold the bus bar.

2. The connection module according to claim 1,
wherein a protruding dimension of the board arrangement portion as measured from the bottom wall is smaller than a protruding dimension of the bus bar arrangement portion as measured from the bottom wall.

3. The connection module according to claim 1,
wherein a plurality of detection conductive paths for detecting the state of the plurality of power storage elements are drawn out from the plurality of power storage modules,
the plurality of detection conductive paths and at least one output conductive path are electrically connected to the circuit board, and
the electronic component on the circuit board multiplexes a plurality of signals input from the plurality of detection conductive paths and outputs the multiplexed signals to the output conductive path.

4. The connection module according to claim 3,
wherein one end portions of a plurality of relay conductive paths are electrically connected to the circuit board, and a connection module-side connector is connected to the other end portions of the plurality of relay conductive paths, and
the plurality of detection conductive paths and the plurality of relay conductive paths are electrically connected to each other by fitting together the connection module-side connector and a power storage module-side connector that is connected to end portions of the plurality of detection conductive paths.

5. The connection module according to claim 4,
wherein the insulating protector has a connector holding portion configured to hold the connection module-side connector.

6. The connection module according to claim 4,
wherein the insulating protector has a conductive path wiring portion in which one or both of the detection conductive paths and the relay conductive paths are to be arranged.

7. The connection module according to claim 6,
wherein an output conductive path is electrically connected to the circuit board, and
the output conductive path is arranged in the conductive path wiring portion.
